(19) United States
(12) Patent Application Publication
(10) Pub. No.: US 2026/0099179 A1
(43) Pub. Date: Apr. 9, 2026

(54) STRUCTURAL BUSBAR FOR POWER DELIVERY IN COMPUTING SYSTEM

(71) Applicant: Tesla, Inc., Austin, TX (US)

(72) Inventors: Rishabh Bhandari, San Carlos, CA (US); Jin Zhao, San Jose, CA (US); Peter Groen, Palo Alto, CA (US); Frank Spiteri, Palo Alto, CA (US); Nigel Adrien Myers, Mountain View, CA (US)

(21) Appl. No.: 19/115,745

(22) PCT Filed: Sep. 27, 2023
(86) PCT No.: PCT/US2023/033811

§ 371 Date: Mar. 26, 2025

Related U.S. Application Data
(60) Provisional application No. 63/377,998, filed on Sep. 30, 2022.

(51) Int. Cl. G06F 1/20; G06F 1/18; G06F 1/183; H05K 7/14; H05K 7/20

(52) U.S. Cl. CPC G06F 1/20; G06F 1/183; G06F 1/189; H05K 7/1487; H05K 7/20772; G06F 2200/201

(57) ABSTRACT

Aspects of this disclosure relate to a structural busbar for power delivery in a computing system. The computing system can include a plurality of computing tiles and a busbar with the plurality of computing tiles positioned thereon. The busbar can provide structural support for the plurality of computing tiles and electrical power to the plurality of computing tiles. In some embodiments, the structural busbar can also provide coolant to each of the computing tiles. In certain embodiments, a structural busbar can provide power and electrical support to any suitable electronic modules.

### CROSS-REFERENCE TO RELATED APPLICATION

This application is a national phase of PCT Patent Application No. PCT/US2023/033811, titled “STRUCTURAL BUSBAR FOR POWER DELIVERY IN COMPUTING SYSTEM,” filed Sep. 27, 2023, which claims the benefit of U.S. Provisional Ser. No. 63/377,998 , titled “INTEGRATED STRUCTURAL COMPUTE PLANE WITH COOLANT, POWER AND SIGNAL DELIVERY,” filed Sep. 30, 2022, the disclosure of which is incorporated herein by reference in its entirety and for all purposes.

### BACKGROUND

### Technological Field

The present disclosure relates generally to busbars in computing systems, and more specifically to integrated power delivery in structural busbars.

### Description of the Related Technology

Certain computing systems can be used in and/or specifically configured for high performance computing and/or computationally intensive applications, such as neural network training, neural network inference, machine learning, artificial intelligence, complex simulations, or the like. In some applications, a computing system can be used to perform neural network training. For example, such neural network training can generate data for an autopilot system for a vehicle (e.g., an automobile), other autonomous vehicle functionality, or Advanced Driving Assistance System (ADAS) functionality.

In high performance computing systems, high-speed connectivity, desirable power performance, and dense integration are generally desirable.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

In one aspect a computing system is disclosed. The computing system can include a plurality of computing tiles. Each computing tile of the plurality of computing tiles can include a plurality of dies and a cooling solution integrated with the plurality of dies. The computing system can include a busbar with the plurality of computing tiles positioned thereon. The busbar can be configured to provide structural support for the plurality of computing tiles and electrical power to the plurality of computing tiles.

In one embodiment, the busbar can include a power layer and a ground layer. The power layer and the ground layer can be electrically connected to each computing tile of the plurality of computing tiles. The busbar can include a plurality of insulating layers. The computing system can further include a first plurality of connectors that electrically couple the plurality of computing tiles to the power layer of the busbar. The busbar can include a second plurality of connectors that electrically couple the plurality of computing tiles to the ground layer of the busbar.

In one embodiment, the busbar can include an integrated inlet manifold configured to deliver coolant to each of the plurality of computing tiles and an integrated outlet manifold configured to receive the coolant from each of the plurality of computing tiles. The integrated inlet manifold and the integrated outlet manifold can each be positioned between layers of the busbar.

In one embodiment, the busbar can include stepped edges dimensioned to slide into a cabinet structure and engage with side rails of the cabinet structure.

In one embodiment, each computing tile of the plurality of computing tiles includes a system on wafer (SoW) that includes the plurality of dies.

In one embodiment, the cooling solution includes a cold plate, the cold plate includes an inlet port configured to receive a coolant and an outlet port configured to discharge the coolant.

In one embodiment, the busbar can include an integrated inlet manifold configured to deliver the coolant to the inlet port of each of the plurality of computing tiles and an integrated outlet manifold configured to receive the coolant from the outlet port of each of the plurality of computing tiles. The integrated inlet manifold and the integrated outlet manifold can each be positioned between layers of the busbar.

In one embodiment, the computing system can include an inlet manifold positioned over the busbar and configured to deliver the coolant to the inlet port of each of the plurality of computing tiles and an outlet manifold positioned over the busbar and configured to receive the coolant from the outlet port of each of the plurality of computing tiles.

In one embodiment, the computing system can include a first host positioned vertically relative to the busbar. The first host can be configured to provide data support to the plurality of computing tiles. The computing system can include a second plurality of computing tiles and a second busbar with the second plurality of computing tiles positioned thereon. The second busbar can be configured to provide structural support for the second plurality of computing tiles and electrical power to the second plurality of computing tiles. The first host can be positioned between the busbar and the second busbar. The computing system can include a second host positioned vertically relative to the second plurality of computing tiles. The computing system can include a cabinet structure in which the busbar, the second busbar, the first host, and the second host can be positioned.

In one aspect, a busbar for supporting and electrically connecting electronic modules is disclosed. The busbar can include a power layer, a ground layer, and a plurality of insulating layers. The busbar can be configured to provide structural support for a plurality of electronic modules. The busbar can be configured to provide electrical power to each electronic module of the plurality of electronic modules.

In one embodiment, the plurality of electronic modules includes computing tiles. Each of the computing tiles can include a plurality of dies and a cooling solution integrated with the plurality of dies.

In one embodiment, the busbar includes an integrated inlet manifold configured to provide a coolant to each of the electronic modules and an integrated outlet manifold configured to receive the coolant from each of the electronic modules.

In one embodiment, the plurality of insulating layers includes two outer insulating layers, the power layer and the ground layer are both positioned between the two outer insulating layers, the integrated inlet manifold is positioned between the two outer insulating, and the integrated outlet manifold is positioned between the two outer insulating layers.

In one embodiment, a surface of the busbar includes connections to both the integrated inlet manifold and the integrated outlet manifold.

In one embodiment, the surface of the busbar further includes connections to the power layer and connections to the ground layer.

In one embodiment, the busbar includes openings in areas over which the plurality of electronic modules is positioned when the plurality of electronic modules are connected to the power layer and the ground layer.

In one aspect, a method of assembling a computing system is disclosed. The method can include providing a busbar including a power layer, a ground layer, and a plurality of insulating layers. The method can include connecting a plurality of computing tiles to the power layer and the ground layer of busbar, such that each computing tile of the plurality of computing tiles is arranged to receive structural support and electrical power from the busbar. Each computing tile of the plurality of computing tiles can include a plurality of dies and a cooling solution integrated with the plurality of dies.

In one embodiment, each computing tile of the plurality of computing tiles includes a system on wafer (SoW) that includes the plurality of dies.

In one embodiment, the cooling solution a cold plate, and the cold plate is integrated with the SoW.

In one embodiment, connecting each computing tiles can also connect each computing tile to an integrated inlet manifold and an integrated outlet manifold of the busbar in the same operation.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Specific implementations will now be described with reference to the following drawings, which are provided by way of example, and not limitation.

FIG. 1A illustrates a system tray according to an embodiment.

FIG. 1B illustrates a computing cabinet according to an embodiment.

FIG. 2A is a schematic diagram of a cross section of an example system tray according to an embodiment.

FIG. 2B is a schematic diagram of a cross section of an example system tray according to an embodiment.

FIG. 2C illustrates a top view of an example system tray according to an embodiment.

FIG. 2D illustrates a perspective view of an example system tray according to an embodiment.

FIG. 2E illustrates a perspective view of an example system tray according to an embodiment with the computing tiles omitted.

FIG. 3A is a schematic diagram of a cross section of a system tray with coolant manifolds integrated into the structural busbar according to an embodiment.

FIG. 3B is a schematic diagram of a cross section of a system tray with coolant manifolds integrated into the structural busbar according to an embodiment.

FIG. 4 is a top view of an illustrative structural busbar according to an embodiment.

FIGS. 5A and 5B are schematic diagrams of a tile power connector according to an embodiment.

FIG. 5C is a schematic diagram of a top view of a tile power connector according to an embodiment.

FIG. 6A illustrates a processing system in accordance with aspects of this disclosure.

FIG. 6B illustrates a system of wafer in accordance with aspects of this disclosure.

FIG. 6C is a perspective view illustrating a portion of the processing system of FIG. 6A in accordance with aspects of this disclosure.

FIG. 7 illustrates a connecting pin and connecting receptacle for connecting a computing tile to a structural busbar according to an embodiment.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals and/or terms can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

As discussed above, certain computing systems can be used in and/or specifically configured for high performance computing and/or computationally intensive applications, such as neural network training, neural network inference, machine learning, artificial intelligence, complex simulations, or the like. In some applications, a computing system can be used to perform neural network training. For example, such neural network training can generate data for an autopilot system for vehicle (e.g., an automobile), other autonomous vehicle functionality, or Advanced Driving Assistance System (ADAS) functionality.

Certain computing systems can include various levels of hierarchy to perform computing tasks. For example, a computing system can include, electronic modules, chips or die, computing tiles that each include a plurality of chips or dies packaged together and integrated with one or more cooling solutions, system trays that include an array of connected computing tiles on a structural busbar, and computing cabinets that each include one or more system tray(s).

This disclosure relates to new system trays for computing systems. The system trays disclosed herein can be configured for high performance computing applications. The system trays disclosed herein can provide high-speed connectivity, desirable power and mechanical and thermal performance, and dense integration.

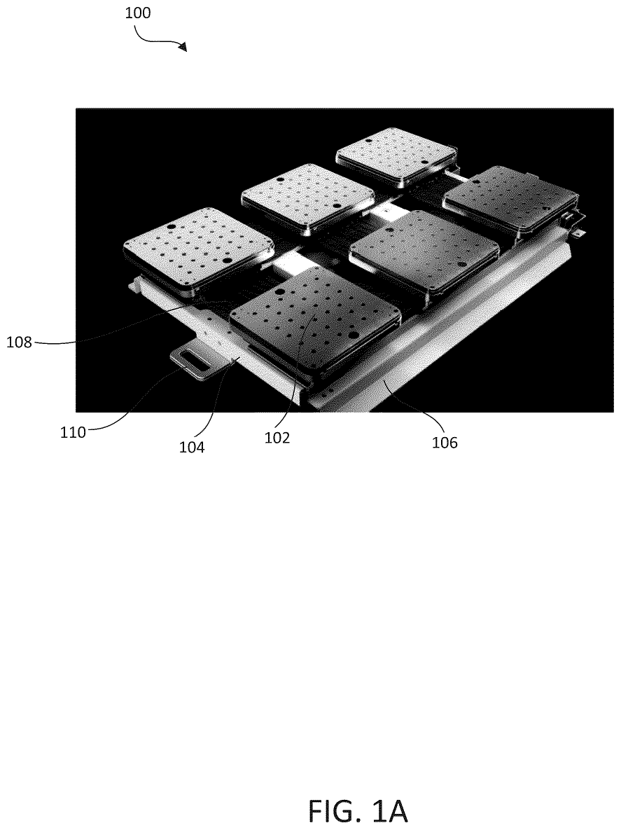

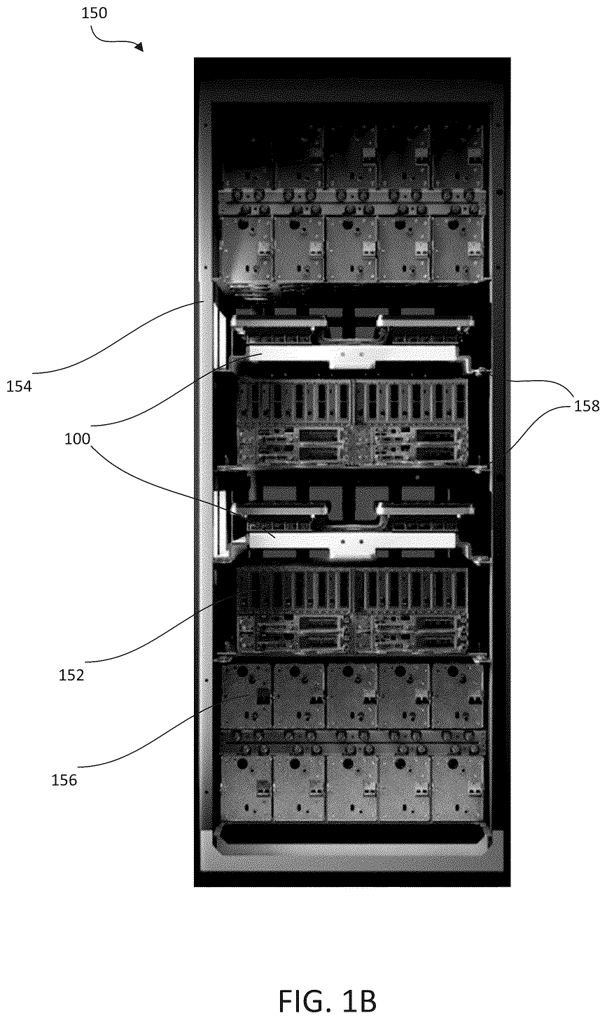

FIG. 1A illustrates a system tray 100 according to an embodiment. As illustrated, the system tray 100 includes an array of computing tiles 102 connected to each other and supported by a structural busbar 104. While computing tiles 102 are illustrated in FIG. 1A, any suitable electronic modules may be included in the system tray 100 and supported by the structural busbar 104. The structural busbar 104 can provide structural support and deliver power to the computing tiles 102 positioned thereon. In certain embodiments, each computing tile 102 includes a system on a wafer that includes an array of dies integrated with a cooling solution (e.g., a cold plate). The computing tiles 102 can be referred to as training tiles in neural network training applications. The computing tiles 102 can be referred to as compute tiles. Any suitable number of computing tiles 102 can be connected to each other on a system tray 100. For example, FIG. 1A illustrates six computing tiles 102 connected to each other. The system tray 100 can include intra-tray signal delivery cables 108 to facilitate the communication between each computing tile 102 and an external connection hub (not shown). The computing tiles 102 are positioned close to each other such that connections between the tiles, such as those established through the intra-tray signal delivery cables 108, are relatively short to promote high-speed connectivity. The system tray 100 can operate at a relatively high power while maintaining mechanical integrity and dissipating sufficient heat to operate at a suitable temperature. The illustrated system tray 100 supports dense integration. For example, the system tray 100 can support a considerable mass while maintaining a relatively small height.

As illustrated in FIG. 1A, the system tray 100 can include stepped edges 106 positioned along the length of opposing sides of the system tray 100. The stepped edges 106 can facilitate sliding the system tray 100 in and out of a cabinet, such as computing cabinet 150 described with respect to FIG. 1B. The system tray 100 can be moved in and out of a cabinet to facilitate blind connections for power, data, and/or coolant. The system tray 100 can include handle 110 to help facilitate moving the system tray 100 in and out of a cabinet.

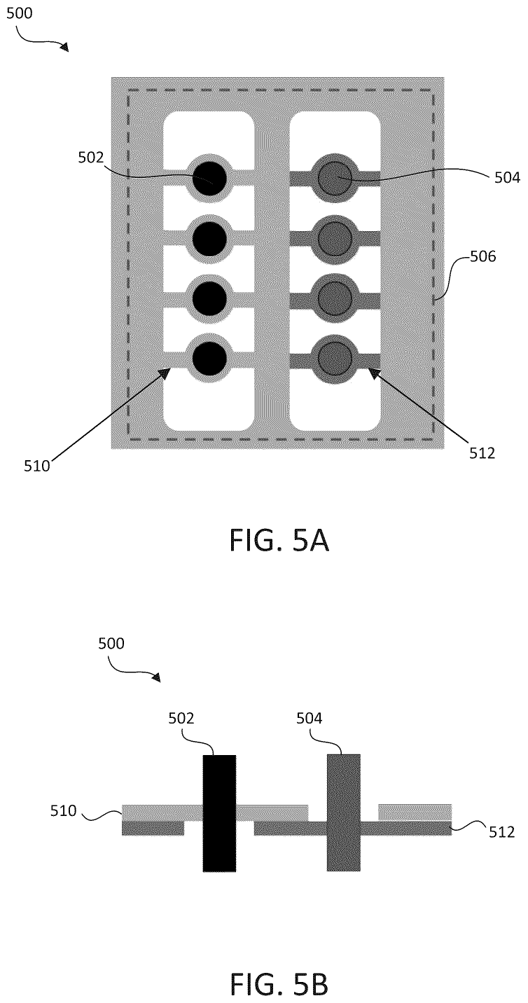

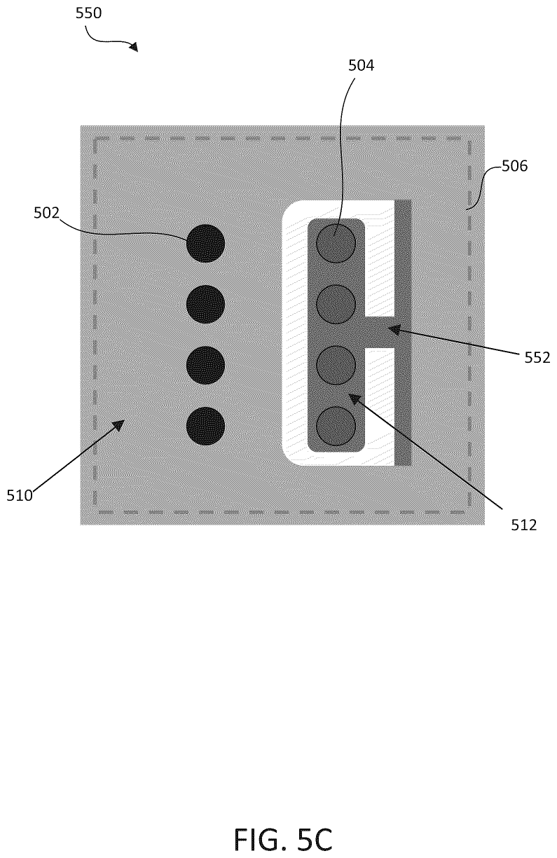

The structural busbar 104 can include multiple layers that provide structural and electrical support for the computing tiles 102. The layers can include insulation layers, one or more power layers, and one or more ground layers. In one embodiment, the structural busbar 104 can include five layers, such as a power layer, an inner insulation layer, and a ground layer all positioned between the two outer insulation layers. The power layer and the ground layer can provide power to the computing tiles 102. For example, the power layer and the ground layer can be made of electrically conductive material. The insulation layers can be made of electrically insulating material, such that the computing tiles 102, the power layer, and the ground layer are generally electrically isolated except where they are electrically connected for power delivery. Tile power connectors, such as the tile power connectors as discussed with respect to FIGS. 5A and 5B, can connect each computing tile 102 to the power layer and ground layer.

In some embodiments, the structural busbar 104 can include integrated manifolds (not shown in FIG. 1A) for distributing coolant to the computing tiles. Such integrated manifolds can be used to cool the structural busbar 104. In one embodiment, manifolds for distributing coolant are integrated into the layers of the structural busbar 104. For example, an inlet manifold can be integrated into a power layer and an outlet manifold can be integrated into a ground layer. The manifolds for distributing coolant can be integrated into the structural busbar any other suitable way. For example, in other layers or as additional layers of the structural busbar 104.

FIG. 1B illustrates a computing cabinet 150 according to an embodiment. The computing cabinet can include system trays 100, hosts 152, power supplies 156, and cabinet structure 154. The hosts 152 can provide data support to the computing tiles 102 and the computing cabinet 150. For example, the hosts 152 can implement ingest processing. The power supplies 156 can facilitate the distribution of power to the computing cabinet 150. For example, the power supplies 156 can include power converters, voltage and/or current supplies, and/or the like based on the power specifications of the computing cabinet 150. The cabinet structure 154 can include side rails 158 that provide structural support for the system trays 100, hosts 152, and power supplies 156. For example, the stepped edges 106 of the system trays 100 can engage the side rails 158 to facilitate sliding the system tray 100 in and out of the cabinet structure 154.

As illustrated in FIG. 1B, the computing cabinet 150 includes a first system tray 100 positioned vertically over a first host 152 and a second system tray 100 positioned vertically over a second host 152. The first host 152 can be positioned between the first system tray 100 and the second system tray 200 as illustrated. The power supplies 156 can be included at the top and bottom of the compute cabinet 150 and positioned vertically relative to the system trays 100 and hosts 152.

The cabinet of structure 154 can include power, data, and coolant connectors that engage with fully inserted system trays 100, hosts 152, and power supplies 156. For example, a fully inserted system tray 100 may be blindly connected to power, data, and coolant connectors. The connectors can facilitate electrical and power connections between the inserted system trays 100, hosts 152, and power supplies 156.

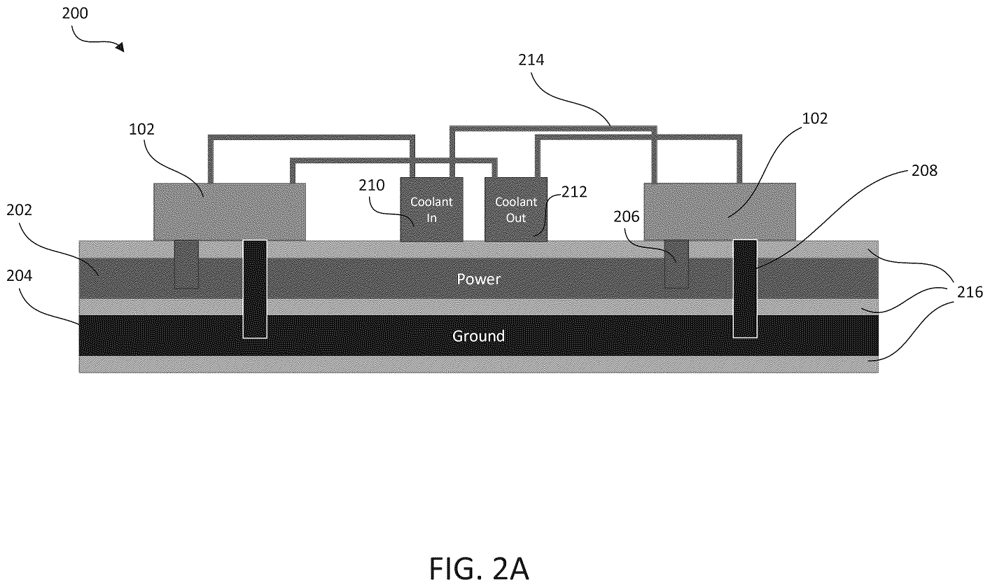

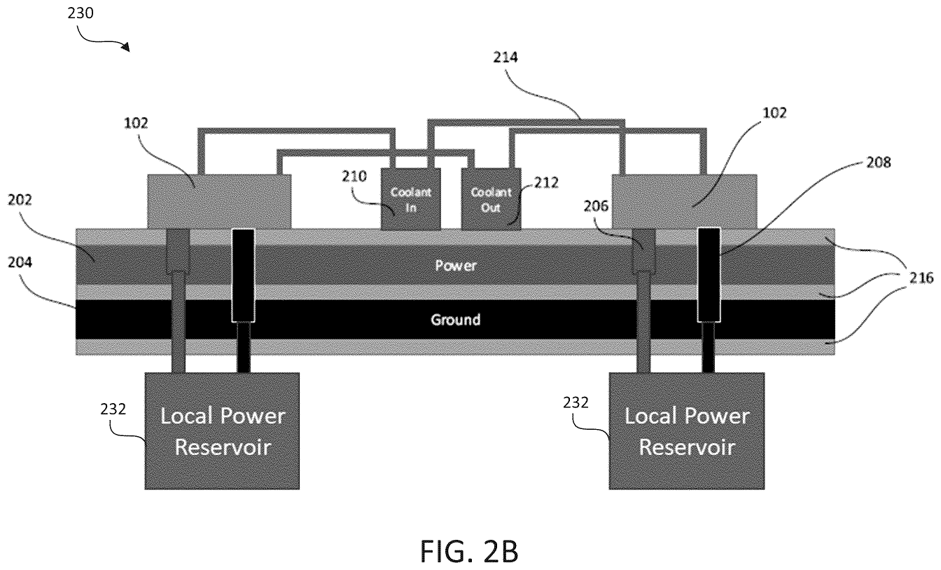

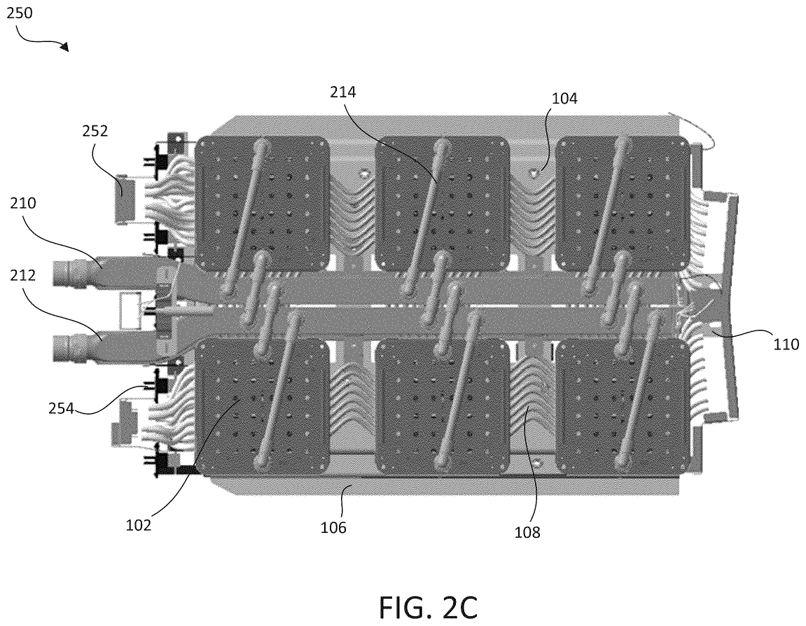

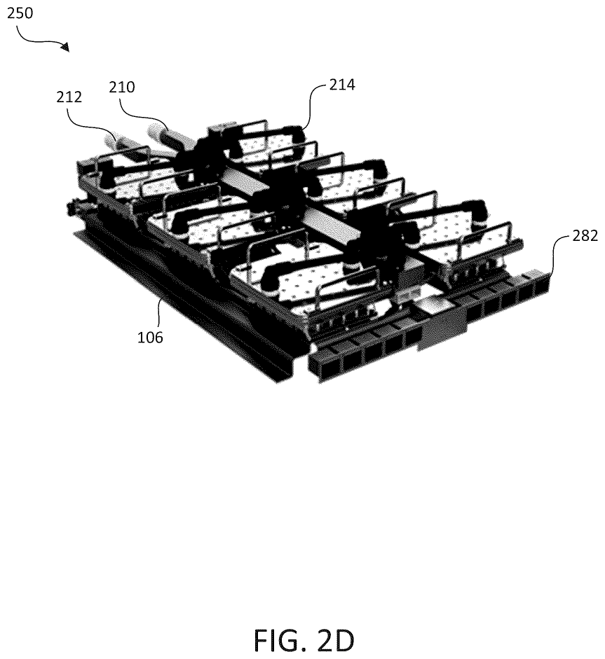

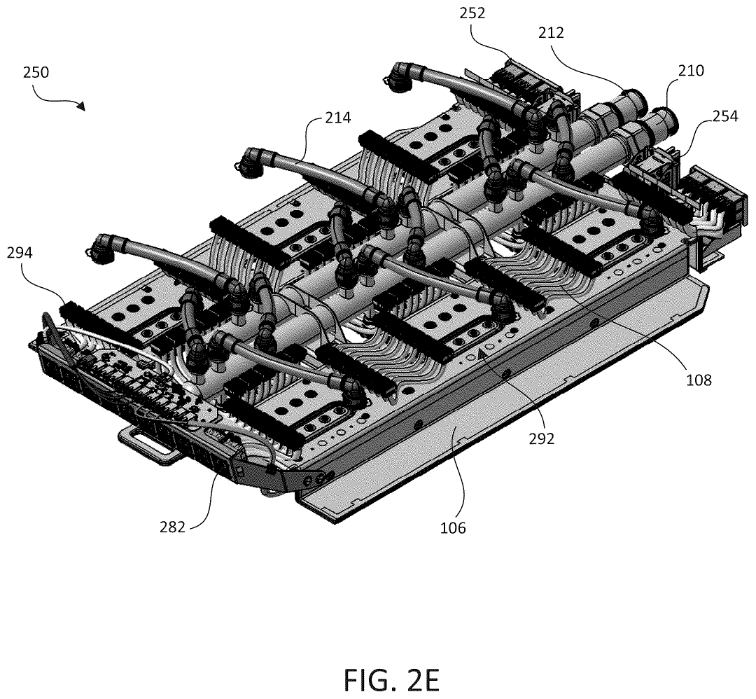

FIGS. 2A-2E are schematic diagrams of example system trays, such as system tray 100, according to an embodiment. FIG. 2A is a schematic diagram of a cross section of the example system tray 200. The features of the system tray 200 are not necessarily illustrated to scale. The system tray 200 includes computing tiles 102, power layer 202, ground layer 204, power connectors 206, ground connectors 208, a coolant inlet manifold 210, a coolant outlet manifold 212, coolant delivery hoses 214, and insulation layers 216. In the system tray 200, a structural busbar includes the power layer 202, the ground layer 204, and insulation layers 216.

The power layer 202 and the ground layer 204 can comprise an electrically conductive material. The power layer 202 and the ground layer 204 can form an electrical power circuit. For example, when the system tray 200 is fully inserted into a computing cabinet, an electrical circuit can be formed by the power layer 202 and ground layer 204. The insulation layers 216 can be made from electrically insulating material. The insulation layers 216 can electrically isolate the computing tiles 102, the power layer 202, and the ground layer 204 except where the computing tiles 102 are connected to the power layer 202 or the ground layer 204.

The power layer 202, ground layer 204, insulation layers 216, power connectors 206, and ground connectors 208 can form a structural busbar, such as the structural busbar 104 of FIG. 1A. The structural busbar can provide structural support and electrical power for the computing tiles 102. For instance, power layer 202, ground layer 204, and insulation layers 216 can be bonded to form a rigid body. The power connectors 206 can electrically couple the computing tiles 102 to the power layer 202. The ground connectors 208 can electrically couple the computing tiles 102 to the ground layer 204. The power connectors 206 and ground connectors 208 can also provide physical coupling to physically connect the computing tiles 102 to the structural busbar. As such, computing tiles 102 can be physically and electrically coupled to the structural busbar in a single connecting action.

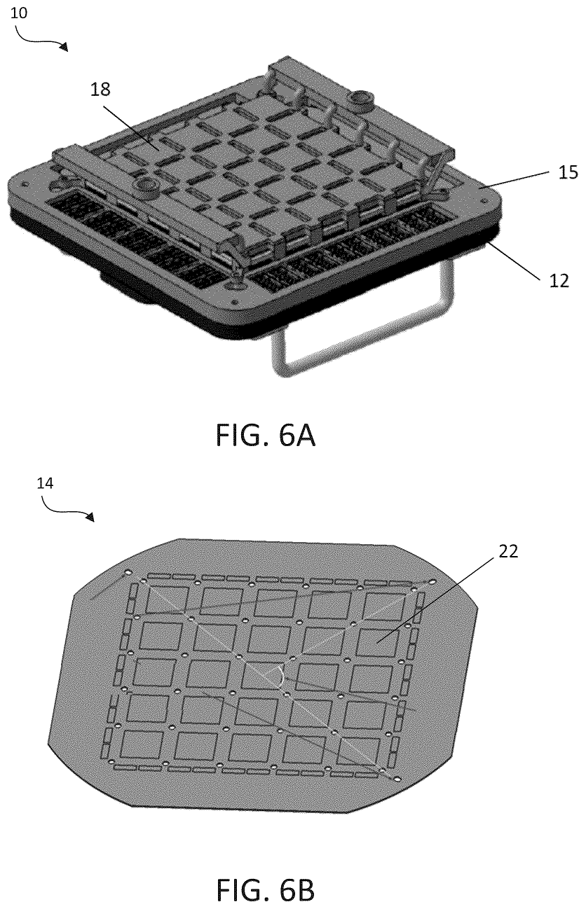

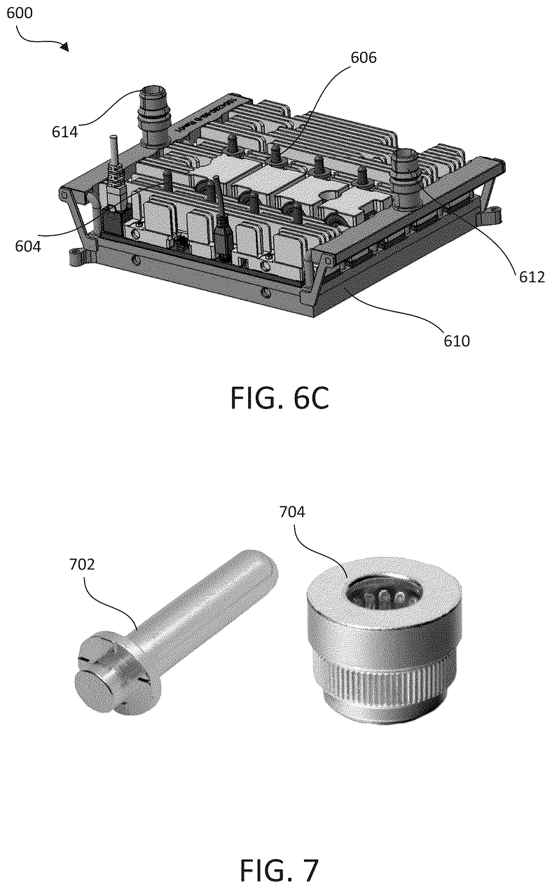

The coolant inlet manifold 210 can deliver coolant into the system tray 200 and the coolant outlet manifold 212 can carry coolant out of the system tray 200. As will be described with more detail with respect to FIG. 6C, computing tiles 102 can include a cold plate that includes various components for receiving coolant into the cold plate, distributing coolant throughout the cold plate to cool a computing tile 102, and discharging coolant from the cold plate. The coolant delivery hoses 214 can transport coolant from the coolant inlet manifold 210 to the computing tiles 102 and transport coolant from the computing tiles 102 to the coolant outlet manifold 212.

FIG. 2B is a schematic diagram of a cross section of the example system tray 230. The features of the system tray 230 are not necessarily illustrated to scale. In addition to the components of system tray 200 of FIG. 2A, tile system tray 230 can also include local power reservoirs 232. The local power reservoirs 232 can be energy storing devices, such as electrical batteries, electrical capacitors, the like, or any suitable combination thereof that can provide power to the system tray 230. For example, the local power reservoirs 232 can provide an additional or alternative power source to the computing tiles 102. The local power reservoirs 232 can be connected directly to the computing tiles 102 using the power connectors 206 and ground connectors 208 and/or can be connected to the power layer 202 and ground layer 204.

FIGS. 2C-2E illustrate various views of a system tray 250 with coolant manifolds positioned over a structural busbar according to an embodiment. FIG. 2C illustrates top view of the system tray 250. FIG. 2D illustrates a perspective view of the system tray 250. FIG. 2E illustrates perspective view of the system tray 250 with the computing tiles 102 omitted.

The system tray 250 can include the computing tiles 102, structural busbar 104, stepped edges 106, intra-tray signal delivery cables 108, and handle 110 as described with reference to system tray 100 of FIG. 1A. The system tray 250 can also include a coolant inlet manifold 210, a coolant outlet manifold 212, coolant delivery hoses 214, system tray data connectors 252, system tray power connectors 254, inter-tray data ports 282, tile power connectors 292, and tile data connectors 294.

As described with reference to FIG. 2A, the coolant inlet manifold 210, coolant outlet manifold 212, and coolant delivery hoses 214 can carry coolant to and from the computing tiles 102. The coolant inlet manifold 210 can be connected to an external coolant source, such as by connectors on a computing cabinet, to receive coolant. The coolant outlet manifold 212 can discharge coolant from the system tray 250.

The system tray data connectors 252 are configured to transfer data to and from the system tray 250. The system tray data connectors 252 are connected to each computing tile 102 via the intra-tray signal delivery cables 108. The system tray power connectors 254 are configured to deliver power to the system tray. The system tray power connectors 254 are connected to each computing tile 102 via the structural busbar 104. The system tray data connectors 252 and system tray power connectors 254 can be connected to external devices, such as the hosts 152 and power supplies 156 as described with reference to FIG. 1B, to receive power and to receive and send data signals.

Each of the system tray data connectors 252, system tray power connectors 254, coolant inlet manifold 210, and coolant outlet manifold 212 can be positioned at the back end of the system tray 250 such that, when the system tray 250 is inserted into a computing cabinet, each is connected to corresponding connectors on the computing cabinet. For example, when the system tray 250 is fully inserted into a computing cabinet, such as computing cabinet 150 as described with respect to FIG. 1B, the system tray data connector 252 can be connected to a data connection on the cabinet structure 154, the system tray power connector 254 can be connected to a power connection on the cabinet structure 154, and the inlet manifold 210 and coolant outlet manifold 212 can be connected to coolant connections on the cabinet structure 154.

The inter-tray data ports 282 are positioned opposite the system tray data connectors 252 and system tray power connectors 254 on the system tray 250. As such, when the system tray 250 is inserted into a computing cabinet, the inter-tray data ports 282 can be accessible. The inter-tray data ports 282 can be connected to the computing tiles 102 via the intra-tray signal delivery cables 108. The inter-tray data ports 282 can facilitate connections between multiple system trays, connections to other computing cabinets, and/or connections to other external sources.

The tile data connectors 294 can connect the computing tiles 102 to the intra-tray signal delivery cables 108 to facilitate the communication of data to and from the computing tiles 102. The tile power connectors 292 can connect the computing tiles 102 to the structural busbar 104 to facilitate the delivery of power to the computing tiles 102. The tile data connectors 294 and the tile power connectors 292 are positioned such that when a computing tile 102 is added to the system tray 250, the computing tile 102 is connected to the tile data connectors 294 and the tile power connectors 292 simultaneously (e.g., in a single mechanical action).

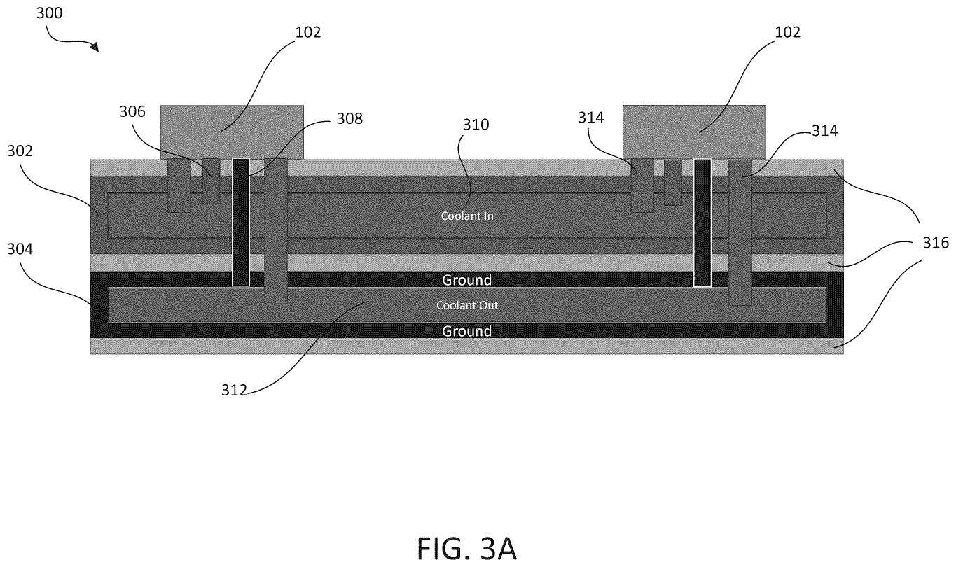

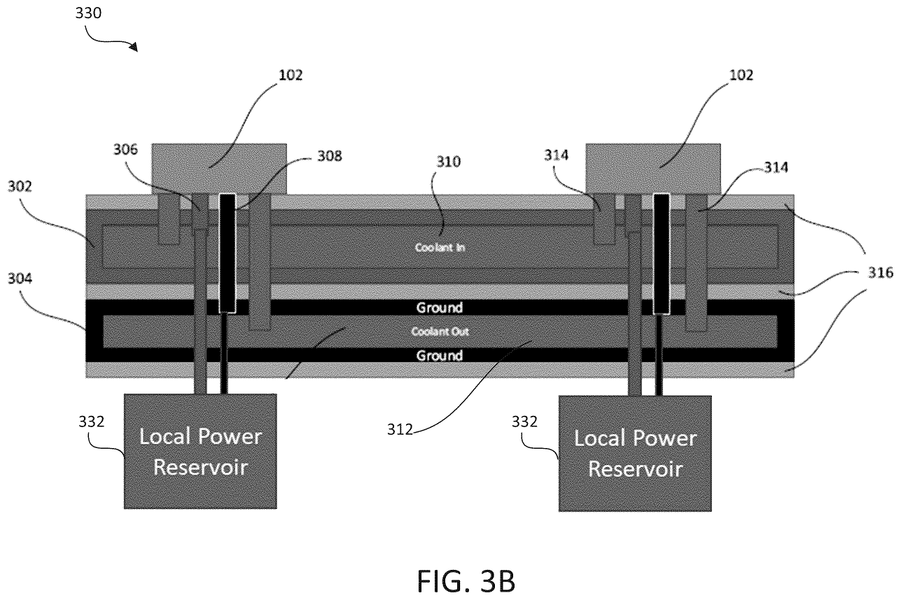

FIG. 3A is a schematic diagram of a cross section of a system tray 300 with coolant manifolds integrated into a structural busbar. The various features of the system tray 300 are not necessarily illustrated to scale. The system tray 300 includes computing tiles 102, power layer 302, ground layer 304, power connectors 306, ground connectors 308, an integrated coolant inlet manifold 310, an integrated coolant outlet manifold 312, coolant vias 314, and insulation layers 316.

The power layer 302 and the ground layer 304 can comprise electrically conductive material. The power layer 302 and the ground layer 304 can form an electrical power circuit. For example, when the system tray 300 is fully inserted into a computing cabinet, an electrical circuit can be formed by the power layer 302 and ground layer 304. The insulation layers 316 can be made from electrically insulating material. The insulation layers 316 can electrically isolate the computing tiles 102, the power layer 302, and the ground layer 304 where the computing tiles 102 are not connected to the power layer 302 or the ground layer 304.

The integrated coolant inlet manifold 310 can deliver coolant into the system tray 300. The integrated coolant outlet manifold 312 can carry coolant out of the system tray 300. As will be described in more detail with respect to FIG. 6C, computing tiles 102 can include a cold plate that includes various components for receiving coolant into the cold plate, distributing coolant throughout the cold plate to cool a computing tile 102, and discharging coolant from the cold plate. Coolant vias 314 can transport coolant from the coolant inlet manifold 210 to the computing tiles 102. Other coolant vias 34 can transport coolant from the computing tiles to the coolant outlet manifold 212.

The power layer 302, ground layer 304, insulation layers 316, power connectors 306, and ground connectors 308 can form a structural busbar, such as the structural busbar 104 as described with respect to FIG. 1A. The structural busbar can provide structural and electrical power support for the computing tiles 102. For instance, power layer 302, ground layer 304, and insulation layers 316 can be bonded to form a rigid body. The power connectors 306 can electrically couple the computing tiles 102 to the power layer 302 and the ground connectors can electrically couple the computing tiles 102 to the ground layer. The power connectors 306 and ground connectors 308 can also provide physical coupling to physically connect the computing tiles 102 to the structural busbar. As such, computing tiles 102 can be physically and electrically coupled to the structural busbar in a single connecting action.

The integrated coolant inlet manifold 310, the integrated coolant outlet manifold 312, and the coolant vias 314 can be incorporated into the structural busbar. The integrated coolant inlet manifold 310 can be positioned between layers of the structural busbar. The integrated coolant outlet manifold 312 can be positioned between layers of the structural busbar. Accordingly, the structural busbar of FIG. 3A can provide structural support for computing tiles, power delivery for computing tiles, and coolant delivery and discharge for computing tiles. The integrated coolant inlet manifold 310 and integrated coolant outlet manifold 312 may provide cooling to the structural busbar. In some embodiments, the structural busbar may include a temperature monitoring grid for monitoring the temperature distribution across the structural busbar. For example, the structural busbar can include one or more thermocouples, resistance temperature detectors (RTDs), thermistors, semiconductor based integrated circuits, and the like, or any suitable combination thereof, that monitor the temperature distribution across the structural busbar.

FIG. 3A illustrates the integrated coolant inlet manifold 310 housed in the power layer 302 and the integrated coolant outlet manifold 312 housed in the ground layer 304. In some embodiments, the integrated coolant inlet manifold 310 and/or the integrated coolant outlet manifold 312 are incorporated into other portions of the structural busbar. For example, the integrated coolant inlet manifold 310 and integrated coolant outlet manifold 312 can be housed in a single layer, such as power layer 302, in one or more of the insulation layers 316, or as additional layers of the structural busbar.

In some embodiments, the computing tiles 102 include incorporated coolant connections, such as inlet port 612 and outlet port 614 as described with respect to FIG. 6C. Computing tiles 102 can be physically coupled to structural busbar through the power connectors 306, ground connectors 308, and the coolant vias 314 and electrically coupled to the structural busbar through the power connectors 306, ground connectors 308. As such, computing tiles 102 can be physically and electrically coupled to the structural busbar and physically coupled to the integrated coolant inlet manifold 310 and the integrated coolant outlet manifold 312 in a single connecting action.

FIG. 3B is a schematic diagram of a cross section of the example system tray 330. The features of the system tray 330 are not necessarily illustrated to scale. In addition to the components of system tray 300 of FIG. 3A, the system tray 330 can also include local power reservoirs 332. The local power reservoirs 332 can be energy storing devices, such as electrical batteries, electrical capacitors, the like, or any suitable combination thereof that can provide power to the system tray 330. For example, the local power reservoirs 332 can provide an additional or alternative power source to the computing tiles 102. The local power reservoirs 332 can be connected directly to the computing tiles 102 using the power connectors 306 and ground connectors 308 and/or can be connected to the power layer 302 and ground layer 304.

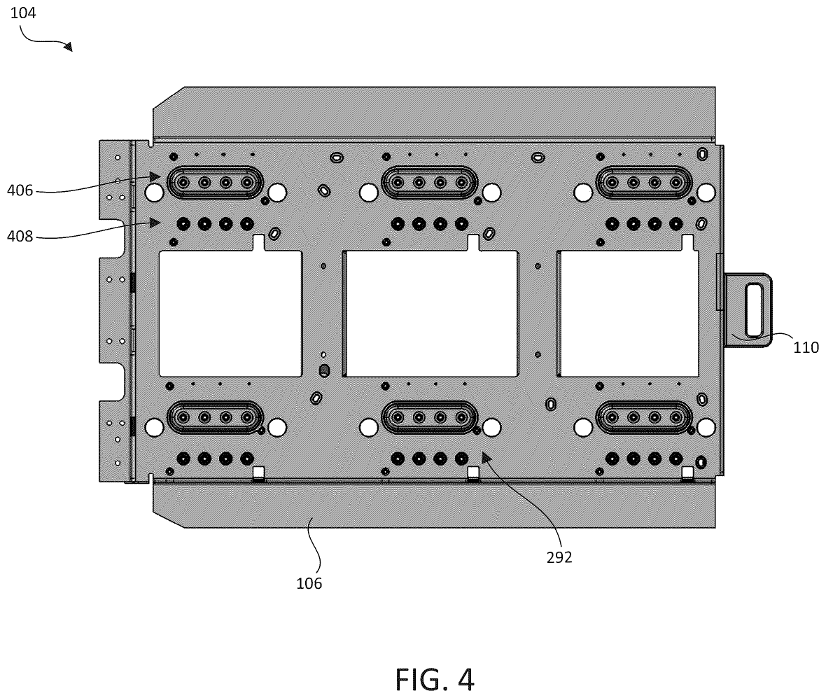

FIG. 4 is a top view of an illustrative structural busbar 104 according to an embodiment. The structural busbar 104 can include the stepped edges 106 and the handle 110 as discussed with reference to FIG. 1A. The structural busbar 104 can also include the tile power connectors 292 as described with reference to FIGS. 2C-2E.

As discussed above, the structural busbar 104 can include multiple layers that provide structural support and electrical power for the computing tiles 102. The layers can include the various layers discussed with respect to FIG. 2A and FIG. 3A, for example. The tile power connectors 292 can connect each computing tile 102 to a power layer and a ground layer of the structural busbar 104. In some embodiments, the structural busbar 104 can include integrated manifolds for distributing coolant to the computing tiles, such as the integrated coolant inlet manifold 310 and the integrated coolant outlet manifold 312 as discussed with reference to FIG. 3A.

Each tile power connector 292 comprises power connectors 406 and ground connectors 408. The power connectors 406 can correspond to the power connectors 206 and/or the power connectors 306, as discussed with reference to FIG. 2A and FIG. 3A. Similarly, the ground connectors 408 can correspond to the ground connectors 208 and/or the ground connectors 308, as discussed with reference to FIG. 2A and FIG. 3A. Although FIG. 4 illustrates that each tile power connectors 292 includes four power connectors 406 and four ground connectors 408, more or fewer power connectors 406 and/or ground connectors 408 may be used. The tile power connectors 292 are described in more detail with respect to FIGS. 5A-5B below.

FIGS. 5A-5B are schematic diagrams of a tile power connector, such as a tile power connector 292, according to an embodiment. FIG. 5A is a schematic diagram of a top view of the tile power connector 500. FIG. 5B is a schematic diagram of a cross section of the tile power connector 500. The various features of the tile power connector 500 are not necessarily illustrated to scale in FIG. 5A and/or FIG. 5B. A structural busbar with the tile connector 500 can implement integrated fusing. The power connector 500 includes device ground connectors 502, device power connectors 504, busbar ground layer 510 and busbar power layer 512. The device ground connectors 502 and/or the device ground connectors 504 can be pins, for example. For illustrative purposes, tile footprint 506 provides an example footprint of a computing tile 102 compared to the tile power connector 500.

The device ground connectors 502 can be pins of a computing tile 102 that extend into the busbar ground layer 510. The device power connectors 504 can be pins of a computing tile 102 that extend into the busbar power layer 512. When the device ground connectors 502 are inserted into the busbar ground layer 510 and the device power connectors 504 are inserted into the busbar power layer 512, an electrical power circuit is established, and power is delivered to the computing tiles 102.

The busbar power layer 512 and the busbar ground layer 510 each comprise built-in sections of thinner conductor cross-sections. The thinner conductor cross-sections can limit the deliverable current to the computing tiles 102 to protect the computing tiles 102 from surging current. The tile power connector 500 can be implemented without electrical fuses integrated into the busbar.

FIG. 5C is a schematic diagram of a top view of a tile power connector 550, such as a tile power connector 292, according to an embodiment. In addition to the components of tile power connector 500 of FIG. 5B, tile power connector 550 can also include electrical fuse 552. In some embodiments, electrical fuse 552 can be integrated into the busbar, such as part of the busbar power layer 512. In some embodiments, one or more other electrical fuses can be external to the busbar. In some embodiments, electrical fuse 552 can include current sensing components and output one or more signals in association with current passing a threshold value.

FIG. 6A illustrates a processing system 10 in accordance with aspects of this disclosure. FIG. 6B illustrates a system on a wafer (SoW) 14 of the processing system 10 in accordance with aspects of this disclosure. In some embodiments, processing system 10 corresponds to the computing tiles 102 of FIG. 1A and/or any other suitable computing tile disclosed herein. The processing system 10 can have a high compute density and dissipation of heat generated by the processing system 10 can significantly affect the performance of the processing system 10. The processing system 10 can be used in and/or specifically configured for high performance computing and/or computation intensive applications, such as neural network training and/or processing, machine learning, artificial intelligence, or the like. The processing system 10 can implement redundancy. In some applications, the processing system 10 can be used for neural network training to generate data for use by an autopilot system of a vehicle (e.g., an automobile), to implement other autonomous vehicle functionality, to implement Advanced Driving Assistance System (ADAS) functionality, or the like.

The processing system 10 can include a heat dissipation structure 12, a SoW 14, an input/output (I/O) frame 15, voltage regulating modules (VRMs), a cooling system 18, a control broad, and/or the like. In the processing system 10, a thermal system includes the heat dissipation structure 12 and the cooling system 18. Each of the illustrated elements of the processing system 10 is a SoW assembly structure. FIG. 6A shows the processing system 10 upside down relative to the system tray 100 illustrated in FIG. 1A.

The heat dissipation structure 12 can dissipate heat from the SoW 14. The heat dissipation structure 12 can include a heat spreader. Such a heat spreader can include a metal plate. Alternatively or additionally, the heat dissipation structure 12 can include a heat sink. The heat dissipation structure 12 can include any suitable material with desirable heat dissipation properties. A thermal interface material can be included between the heat dissipation structure 12 and the SoW 14 to reduce and/or minimize heat transfer resistance.

In FIG. 6A, the processing system 10 includes a SoW 14 positioned between the heat dissipation structure 12 and the cooling system 18. As illustrated in FIG. 6B, the SoW 14 can include an array of integrated circuit (IC) dies 22. The IC dies 22 can be embedded in a molding material. The SoW 14 can have a high compute density. The IC dies 22 can be semiconductor dies, such as silicon dies. The array of IC dies 22 can include any suitable number of IC dies 22. For example, the array of IC dies 22 can include 16 IC dies 22, 25 IC dies 22, 36 IC dies 22, or 49 IC dies 22. The SoW 14 can be an Integrated Fan-Out (InFO) wafer, for example. InFO wafers can include a plurality of routing layers over an array of IC dies 22. For example, an InFO wafer can include 4, 5, 6, 8, or 10 routing layers in certain applications. The routing layers of the InFO wafer can provide signal connectivity between the ICs dies 22 and/or to external components. The SoW 14 can have a relatively large diameter, such as a diameter in a range from 10 inches to 15 inches. As one example, the SoW 14 can have a 12 inch diameter.

The I/O frame 15 can contribute to the structural integrity of the processing system 10. The I/O frame 15 can provide support to the VRMs and keep the VRMs in place.

The VRMs can be positioned such that each VRM is stacked with an IC die 22 of the SoW 14. In the processing system 10, there is high density packing of the VRMs. Accordingly, the VRMs can consume significant power and generate heat. The VRMs are configured to receive a direct current (DC) supply voltage and supply a lower output voltage to a corresponding IC die 22 of the SoW 14. The VRMs can be connected to the structural busbar, such as structural busbar 104, to provide the VRMs the supply voltage.

The cooling system 18 can provide active cooling for the VRMs and the SoW 22. The cooling system 18 can receive a coolant from a coolant inlet manifold. The cooling system 18 can discharge the coolant to a coolant output manifold. The cooling system 18 can provide active cooling for the control board. The cooling system 18 can include metal with flow paths for heat transfer fluid, such as coolant, to flow through. In the assembled processing system 10, the cooling system 18 can be bolted to the heat dissipation structure 12. This can provide structural support for the SoW 14 and/or can reduce the chance of the SoW 14 breaking. Thermal interface material can be included between the cooling system 18 and the control board to reduce and/or minimize heat transfer resistance.

The control board can include electrical components. Electronics of the control board can provide control signals for the VRMs. The control board can include electronics to control operation of the SoW 14.

FIG. 6C is a perspective view illustrating a portion 600 of the processing system 10 in accordance with aspects of this disclosure. Portion 600 of the processing system 10 illustrates a cold plate 610, power connector pins 606, and ground connector pins 604. The cold plate 610 can implement the cooling system 18 of FIG. 6A, for example.

The cold plate 610 can include various inlet ports, such as inlet port 612, inlet manifolds, mechanical supports, flow channels, fins, outlet manifolds and outlet ports, such as outlet port 614. The cold plate 610 can also include openings (also referred to as receptacles or slots) for pass through connectors, such as power connector pins 606 and ground connector pins 604, that provide for thermal, power, and/or communication connectivity through the cold plate 610. In some implementations, the cold plate may be formed of machined copper parts that have been brazed. The cold plate body can be formed of any other suitable material. The cold plate body can include an array of cooling elements such as fins.

The cold plate 610 can facilitate active cooling of the processing system 10 through coolant. The cold plate 610 can receive coolant from a coolant inlet manifold of a system tray at the inlet port 612 to the cold plate 610, distribute the coolant through the flow channels of the cold plate 610 to cool the processing system 10, and discharge coolant to a coolant outlet manifold of the system tray through the outlet port 614.

In some embodiments, the power connector pins 606 and the ground connector pins 604 correspond to the device power connectors 504 and the device ground connectors 502 described with reference to FIGS. 5A-5B. As illustrated in FIG. 6C the power connector pins 606, ground connector pins 604, inlet port 612, and outlet port 614 are positioned on the same side of the processing system 10. As such, structural, electrical, and coolant connections can be established in the same connecting action. For example, the processing system 10 can be physically and electrically coupled to a structural busbar and physically coupled to an integrated coolant inlet manifold and an integrated coolant outlet manifold in the structural busbar in a single connecting action. The structural busbar can include a surface with power connections, ground connections, and coolant path connections to facilitate such connections.

FIG. 7 illustrates a connecting pin 702 and connecting receptacle 704 according to an embodiment. The connecting pin 702 can be inserted into the connecting receptacle 704 to establish an electrical and physical coupling between the connecting pin 702 and the connecting receptacle 704. In some embodiments, the connecting pin 702 corresponds to the device ground connectors 502 and device power connectors 504 discussed with reference to FIGS. 5A-5B. However, any other suitable components may be used in place of the connection pin 702. In some embodiments, the connecting receptacle 704 is incorporated in a structural busbar, such as the power connectors 406 and the ground connectors 408 of structural busbar 104 of FIG. 4. However, any other suitable components can be used in place of the connecting receptacle 704.

In some embodiments, the connecting pin 702 and/or the connecting receptacle 704 may comprise built in electrical fuses. The built in electrical fuses may help regulate the amount of electrical current that can travel through the connecting pin 702 and/or the connecting receptacle 704.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to. ” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

The foregoing description has been described with reference to specific embodiments. However, the illustrative discussions above are not intended to be exhaustive or to limit the inventions to the precise forms described. Many modifications and variations are possible in view of the above teachings. Others skilled in the art are thereby enabled to best utilize the techniques and various embodiments with various modifications as suited to various uses.

Although the disclosure and examples have been described with reference to the accompanying drawings, various changes and modifications will become apparent to those skilled in the art. Such changes and modifications are to be understood as being included within the scope of the disclosure.

What is claimed is:

1. A computing system comprising:
a plurality of computing tiles, wherein each computing tile of the plurality of computing tiles comprises a plurality of dies and a cooling solution integrated with the plurality of dies; and
a busbar with the plurality of computing tiles positioned thereon, the busbar configured to provide structural support for the plurality of computing tiles and electrical power to the plurality of computing tiles.

2. The computing system of claim 1, wherein
the busbar comprises:
a power layer;
a ground layer; wherein the power layer and the ground layer are electrically connected to each computing tile of the plurality of computing tiles; and
a plurality of insulating layers; and
the computing system further comprises:
a first plurality of connectors that electrically couple the plurality of computing tiles to the power layer of the busbar; and
a second plurality of connectors that electrically couple the plurality of computing tiles to the ground layer of the busbar.

3. The computing system of claim 2, wherein the busbar further comprises:
an integrated inlet manifold configured to deliver coolant to each of the plurality of computing tiles; and
an integrated outlet manifold configured to receive the coolant from each of the plurality of computing tiles, the integrated inlet manifold and the integrated outlet manifold each being positioned between layers of the busbar.

4. The computing system of claim 1, wherein the busbar comprises stepped edges dimensioned to slide into a cabinet structure and engage with side rails of the cabinet structure.

5. The computing system of claim 1, wherein each computing tile of the plurality of computing tiles comprises a system on wafer (SoW) that comprises the plurality of dies.

6. The computing system of claim 1, wherein the cooling solution comprises a cold plate, the cold plate comprises an inlet port configured to receive a coolant and an outlet port configured to discharge the coolant.

7. The computing system of claim 6, wherein the busbar further comprises:
an integrated inlet manifold configured to deliver the coolant to the inlet port of each of the plurality of computing tiles; and
an integrated outlet manifold configured to receive the coolant from the outlet port of each of the plurality of computing tiles, the integrated inlet manifold and the integrated outlet manifold each being positioned between layers of the busbar.

8. The computing system of claim 6, further comprising:
an inlet manifold positioned over the busbar and configured to deliver the coolant to the inlet port of each of the plurality of computing tiles; and
an outlet manifold positioned over the busbar and configured to receive the coolant from the outlet port of each of the plurality of computing tiles.

9. The computing system of claim 1, further comprising:
a first host positioned vertically relative to the busbar, the first host configured to provide data support to the plurality of computing tiles;
a second plurality of computing tiles;
a second busbar with the second plurality of computing tiles positioned thereon, the second busbar configured to provide structural support for the second plurality of computing tiles and electrical power to the second plurality of computing tiles, the first host being positioned between the busbar and the second busbar;
a second host positioned vertically relative to the second plurality of computing tiles; and
a cabinet structure in which the busbar, the second busbar, the first host, and the second host are positioned.

10. A busbar for supporting and electrically connecting electronic modules, the busbar comprising:
a power layer;
a ground layer; and
a plurality of insulating layers;
wherein the busbar is configured to provide structural support for a plurality of electronic modules, and wherein the busbar is configured to provide electrical power to each electronic module of the plurality of electronic modules.

11. The busbar of claim 10, wherein the plurality electronic modules comprise computing tiles, wherein each of the computing tiles comprises a plurality of dies and a cooling solution integrated with the plurality of dies.

12. The busbar of claim 10, further comprising:
an integrated inlet manifold configured to provide a coolant to each of the electronic modules; and
an integrated outlet manifold configured to receive the coolant from each of the electronic modules.

13. The busbar of claim 12, wherein:
the plurality of insulating layers includes two outer insulating layers;
the power layer and the ground layer are both positioned between the two outer insulating layers;
the integrated inlet manifold is positioned between the two outer insulating; and
the integrated outlet manifold is positioned between the two outer insulating layers.

14. The busbar of claim 12, wherein a surface of the busbar comprises connections to both the integrated inlet manifold and the integrated outlet manifold.

15. The busbar of claim 14, wherein the surface of the busbar further comprises connections to the power layer and connections to the ground layer.

16. The busbar of claim 10, wherein the busbar comprises openings in areas over which the plurality of electronic modules are positioned when the plurality of electronic modules are connected to the power layer and the ground layer.

17. A method of assembling a computing system, the method comprising:
providing a busbar comprising a power layer, a ground layer, and a plurality of insulating layers; and
connecting a plurality of computing tiles to the power layer and the ground layer of busbar, such that each computing tile of the plurality of computing tiles is arranged to receive structural support and electrical power from the busbar,
wherein each computing tile of the plurality of computing tiles comprises a plurality of dies and a cooling solution integrated with the plurality of dies.

18. The method of claim 17, wherein each computing tile of the plurality of computing tiles comprises a system on wafer (SoW) that comprises the plurality of dies.

19. The method of claim 18, wherein the cooling solution a cold plate, and the cold plate is integrated with the SoW.

20. The method of claim 17, wherein the connecting each computing tiles also connects each computing tile to an integrated inlet manifold and an integrated outlet manifold of the busbar in the same operation.
